(19) United States
(12) Patent Application Publication
(10) Pub. No.: US 2026/0072095 A1
(43) Pub. Date: Mar. 12, 2026

(54) Electronic Device for Detecting Abnormality of Battery and Operating Method of the Electronic Device

(71) Applicant: LG Energy Solution, Ltd., Seoul (KR)

(72) Inventors: Sung Wook Choi, Daejeon (KR); Hyun Jun Lee, Daejeon (KR); Geum Bee Kim, Daejeon (KR); Jae Wook Shin, Daejeon (KR)

(73) Assignee: LG Energy Solution, Ltd., Seoul (KR)

(21) Appl. No.: 19/106,368

(22) PCT Filed: Aug. 1, 2023
(86) PCT No.: PCT/KR2023/011213

§ 371 Date: Feb. 25, 2025

(30) Foreign Application Priority Data
Sep. 6, 2022 (KR) 10-2022-0113110

(51) Int. Cl. G01R 31/396; G01R 31/367

(52) U.S. Cl. CPC G01R 31/396; G01R 31/367

(57) ABSTRACT

An electronic device obtains input data through a detection circuit, standardizes each of column vectors of the input data to obtain standardized data for the input data, obtains determination reference data based on the standardized data, and determines first state abnormality and/or second state abnormality of each of the M battery cells based on values indicated by the entries of respective row vectors of the determination reference data. The first state abnormality is determined based on a learning-based model, and the second state abnormality is determined based on a scheme other than the learning-based model.

### CROSS-REFERENCE TO RELATED APPLICATION

The present application claims priority from Korean Patent Application No. 10-2022-0113110, filed on Sep. 6, 2022, all of which are hereby incorporated herein by reference in their entireties.

### TECHNICAL FIELD

Embodiments disclosed herein relate to an electronic device for detecting abnormality of a battery and an operating method of the electronic device.

### BACKGROUND

Secondary batteries, which are easy to apply depending on a product group and have electrical characteristics such as high energy density, are generally used not only in portable devices but also in electric vehicles (EV), hybrid electric vehicles (HEV), etc., driven by an electrical drive source.

Types of secondary batteries widely used at the present time include lithium ion batteries, lithium polymer batteries, nickel cadmium batteries, nickel hydrogen batteries, nickel zinc batteries, and so forth. An operating voltage of a unit secondary battery cell, i.e., a unit battery cell, is about 2.5 to 4.5 volts (V). Therefore, when a higher output voltage is required, a battery pack is formed by connecting a plurality of battery cells in series. In addition, a battery pack may be constructed by connecting multiple battery cells in parallel depending on a charge/discharge capacity required for the battery pack. Thus, the number of battery cells included in the battery pack may be set variously depending on a required output voltage or charge/discharge capacity.

### SUMMARY OF THE INVENTION

### Technical Problem

A battery pack may include a plurality of battery cells connected in series and/or in parallel. As a result, even when a battery cell in an abnormal state exists among the plurality of battery cells, it may not be easy to detect abnormality in the battery cell.

Therefore, there is a need for a method for detecting a battery cell in an abnormal state among a plurality of battery cells.

Technical problems of the embodiments disclosed herein are not limited to the above-described technical problems, and other unmentioned technical problems would be clearly understood by one of ordinary skill in the art from the following description.

### Technical Solution

An electronic device according to an embodiment disclosed herein includes a battery module including M battery cells, M being an integer greater than or equal to 2, a detection circuit configured to obtain state values relate to states of the M respective battery cells, and a processor, in which the processor is configured to obtain input data through the detection circuit, wherein the input data is expressible as an M×N matrix, M×N entries of the input data indicate the state values of the M respective battery cells at different points in time, and N indicates a number of the points in time for obtaining the state values of the M respective battery cells, to standardize column vectors of the input data to obtain standardized data for the input data, wherein each of the column vectors comprises the entries of the input data obtained at an identical point in time, to obtain determination reference data based on the standardized data, and to determine first state abnormality and/or second state abnormality of each of the M battery cells based on values indicated by respective row vectors of the determination reference data, in which the first state abnormality is determined based on a learning-based model, and the second state abnormality is determined based on a scheme other than the learning-based model.

In an embodiment, the processor may be further configured to identify, from among the respective row vectors of the determination reference data, a row vector comprising at least one value less than or equal to a reference threshold standardized score, to obtain an output vector for the identified row vector based on the learning-based model, and to determine the first state abnormality of a battery cell corresponding to the identified row vector, based on the output vector.

In an embodiment, the processor may be further configured to remove an offset from the entries of respective row vectors of the input data and to standardize each of the column vectors of the offset-removed input data to obtain the standardized data, in which the offset is set for each of the respective row vectors of the input data, and the offset is set as a value of a first entry from among the entries of the respective row vectors of the input data.

In an embodiment, the processor may be further configured to smooth the entries of the respective row vectors of the input data and to standardize each of the column vectors of the smoothed input data to obtain the standardized data.

In an embodiment, the processor may be further configured to obtain a window average value of each row vector of the standardized data as the determination reference data and to determine the first state abnormality and/or the second state abnormality of each of the M battery cells based on the window average values of the respective row vectors of the determination reference data, in which the window average values are average values of the entries of the respective row vectors of the standardized data included in different time windows, and the time windows do not overlap one another.

In an embodiment, the processor may be further configured to obtain change amounts of the entries of the respective row vectors of the standardized data as the determination reference data and to determine first state abnormality and/or second state abnormality of each of the M battery cells based on the change amounts of the entries of respective row vectors of the determination reference data.

In an embodiment, the processor may be further configured to identify a sum of the entries of each respective row vector of the determination reference data, to identify, from among the row vectors of the determination reference data, a row vector for which its sum is less than or equal to a threshold sum value, and to determine that a battery cell corresponding to the identified row vector has the second state abnormality.

In an embodiment, the learning-based model may be an auto encoder, and the auto encoder may be trained based on state values of normal battery cells.

An operating method of an electronic device according to an embodiment disclosed herein includes obtaining input data through a detection circuit of the electronic device, wherein the input data is expressible as an M×N matrix, M×N entries of the input data indicate the state values of M respective battery cells of the electronic device at different points in time, and N indicates a number of points in time for obtaining the state values of the M respective battery cells, standardizing column vectors of the input data to obtain standardized data for the input data, wherein each of the column vectors comprises the entries of the input data obtained at an identical point in time, obtaining determination reference data based on the standardized data, and determining first state abnormality and/or second state abnormality of each of the M battery cells based on values indicated by the entries of respective row vectors of the determination reference data, in which the first state abnormality is determined based on a learning-based model, and the second state abnormality is determined based on a scheme other than the learning-based model.

In an embodiment, the determining of the first state abnormality and/or the second state abnormality includes identifying, from among the respective row vectors of the determination reference data, a row vector comprising at least one value less than or equal to a reference threshold standardized score, obtaining an output vector for the identified row vector based on the learning-based model, and determining the first state abnormality of a battery cell corresponding to the identified row vector, based on the output vector.

In an embodiment, the obtaining of the standardized data includes removing an offset from the entries of respective row vectors of the input data and standardizing each of the column vectors of the offset-removed input data to obtain the standardized data, in which the offset is set for each of the respective row vectors of the input data, and the offset is set as a value of a first entry from among the entries of the respective row vectors of the input data.

In an embodiment, the obtaining of the standardized data includes smoothing the entries of the respective row vectors of the input data and standardizing each of the column vectors of the smoothed input data to obtain the standardized data.

In an embodiment, the obtaining of the determination reference data includes obtaining a window average value of the row vectors of the standardized data as the determination reference data, and the determining of the first state abnormality and/or the second state abnormality includes determining the first state abnormality and/or the second state abnormality of each of the M battery cells based on the window average values of the respective row vectors of the determination reference data, in which the window average values are average values of the entries of the respective row vectors of the standardized data included in different time windows, and the time windows do not overlap one another.

In an embodiment, the obtaining of the determination reference data includes obtaining change amounts of the entries of respective row vectors of the standardized data as the determination reference data, and the determining of the first state abnormality and/or the second state abnormality includes determining the first state abnormality and/or the second state abnormality of each of the M battery cells based on the change amounts of the entries of respective row vectors of the determination reference data.

In an embodiment, the determining of the first state abnormality and/or the second state abnormality includes identifying a sum of the entries of each respective row vector of the determination reference data, identifying, from among the row vectors of the determination reference data, a row vector for which its sum is less than or equal to a threshold sum value, and determining that a battery cell corresponding to the identified row vector has the second state abnormality.

### Advantageous Effects

An electronic device and an operating method thereof according to various embodiments disclosed herein may detect a battery cell in an abnormal state among a plurality of battery cells.

The effects of an electronic device for detecting abnormality of a battery and an operating method of the electronic device according to the disclosure of the present document are not limited to the effects mentioned above, and other effects not mentioned will be clearly understood by those of ordinary skill in the art according to the disclosure of the present document.

### BRIEF DESCRIPTION OF THE DRAWINGS

FIG. 1 is a block diagram of an electronic device in a network environment, according to various embodiments of the present disclosure.

FIG. 2 is a flowchart illustrating operations of an electronic device according to an embodiment of the present disclosure.

FIG. 3 is a flowchart illustrating operations of an electronic device according to an embodiment of the present disclosure.

FIG. 4A illustrates input data.

FIG. 4B illustrates smoothed input data.

FIG. 4C illustrates offset-removed input data.

FIG. 4D illustrates standardized data of offset-removed input data.

FIG. 4E illustrates offset-removed standardized data. FIG. 4F illustrates window average data of standardized data.

FIG. 4G illustrates change amount data of window average data.

FIG. 5 is a flowchart illustrating operations of an electronic device according to an embodiment of the present disclosure.

FIG. 6 is a flowchart illustrating operations of an electronic device according to an embodiment of the present disclosure.

With regard to the description of the drawings, similar reference numerals may be used to refer to similar or related components.

### DETAILED DESCRIPTION

Hereinafter, embodiments of the present disclosure will be described with reference to the accompanying drawings. However, the description is not intended to limit the present disclosure to particular embodiments, and it should be construed as including various modifications, equivalents, and/or alternatives according to the embodiments of the present disclosure.

It should be appreciated that embodiments of the present document and the terms used therein are not intended to limit the technological features set forth herein to a particular embodiment and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}”, “2^{nd},” “first”, “second”, “A”, “B”, “(a)”, or “(b)” may be used to simply distinguish a corresponding component from another, and does not limit the components in other aspect (e.g., importance or order), unless mentioned otherwise.

Herein, it is to be understood that when an element (e.g., a first element) is referred to, with or without the term “operatively” or “communicatively”, as “connected with”, “coupled with”, or “linked with”, or “coupled to” or “connected to” to another element (e.g., a second element), it means that the element may be connected with the other element directly (e.g., wiredly or wirelessly), or indirectly (e.g., via a third element).

A method according to various embodiments disclosed herein may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices directly. If distributed online, at least part of the computer program product may be temporarily generated or at least temporarily stored in the machine-readable storage medium, such as memory of the manufacturer's server, a server of the application store, or a relay server.

According to embodiments disclosed herein, each component (e.g., a module or a program) of the above-described components may include a single entity or multiple entities, and some of the multiple entities may be separately disposed in different components. According to various embodiments disclosed herein, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to embodiments disclosed herein, operations performed by the module, the program, or another component may be carried out sequentially, in parallel, repeatedly, or heuristically, or one or more of the operations may be executed in a different order or omitted, or one or more other operations may be added.

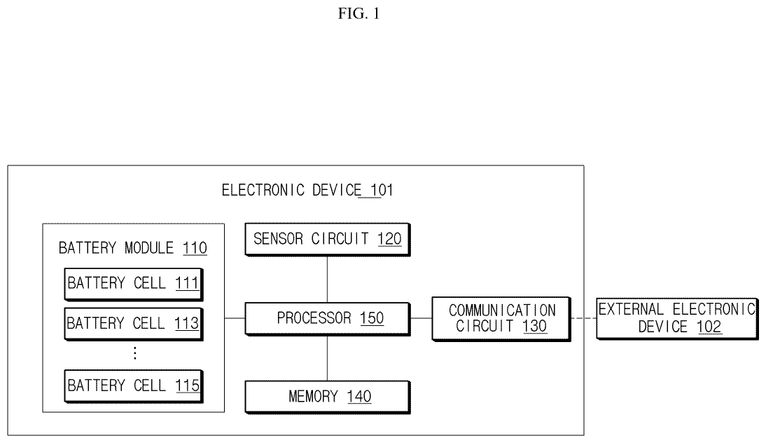

FIG. 1 is a block diagram of an electronic device 101 according to an embodiment of the present disclosure.

Referring to FIG. 1, the electronic device 101 may include a battery module 110, a sensor circuit 120, a communication circuit 130, a memory 140, and a processor 150. According to an embodiment, at least one component (e.g., the battery module 110) of the electronic device 101 shown in FIG. 1 may be replaced with another component (e.g., a battery cell including a plurality of battery modules 110). According to an embodiment, at least one component (e.g., the battery module 110) of the electronic device 101 shown in FIG. 1 may be provided in plural. According to an embodiment, at least one component (e.g., the sensor circuit 120 or the communication circuit 130) of the electronic device 101 shown in FIG. 1 may be excluded from the electronic device 101. According to an embodiment, the electronic device 101 may further include at least one component (e.g., a power unit (e.g., a motor), a display, an input device, or an output device) in addition to components shown in FIG. 1.

In an embodiment, the electronic device 101 may be a battery management system (BMS). When the electronic device 101 is implemented with a BMS, the electronic device 101 may supply power of the battery module 110 to an external component (e.g., a motor).

In an embodiment, the electronic device 101 may be a battery swapping station (BSS). When the electronic device 101 is implemented with a battery swapping station, the electronic device 101 may include a plurality of slots for storing and/or charging the plurality of battery modules 110.

In an embodiment, the battery module 110 may supply power to one or more components of the electric device 101. In an embodiment, the battery module 110 may be attached to or detached from the electronic device 101.

In an embodiment, the battery module 110 may include one or more battery cells 111, 113, or 115. The 111 one or more battery cells 111, 113, or 115 may be included in a state of being electrically connected to one another in the battery module 110. For example, the one or more battery cells 111, 113, or 115 may be connected to one another in series and/or in parallel. According to an embodiment, the one or more battery cells 111, 113, or 115 may be included in a state of being electrically separated from one another in the battery module 110.

In an embodiment, the sensor circuit 120 may obtain information related to the battery module 110. In an embodiment, the sensor circuit 120 may obtain values (or information) related to respective states of the one or more battery cells 111, 113, or 115. In an embodiment, the values related to the states may indicate one or more values of voltages, currents, resistances, states of charge (SoC), states of health (SoH), or temperatures of a battery cell or combinations thereof. Hereinbelow, the value related to the state may be referred to as a ‘state value’.

In an embodiment, the sensor circuit 120 may provide information (e.g., state values) of the one or more battery cells 111, 113, or 115 to the processor 150.

In an embodiment, the communication circuit 130 may establish a wired communication channel and/or a wireless communication channel between the electronic device 101 and an external electronic device 102, and transmit and receive data to and from the external electronic device 102 through the established communication channel.

In an embodiment, the communication circuit 130 may perform communication based on at least one radio access technology (RAT). In an embodiment, the communication circuit 130 may transmit and receive data to and from the external electronic device 102 by using at least one RAT.

In an embodiment, the memory 140 may include a volatile and/or a nonvolatile memory.

In an embodiment, the memory 140 may store data used by at least one component (e.g., the processor 150 or the sensor circuit 120) of the electronic device 101. For example, the data may include software (or an instruction related thereto), input data, or output data. In an embodiment, an instruction, when executed by the processor 150, may cause the electronic device 101 to perform operations defined by the instruction.

In an embodiment, the processor 150 may execute software to control at least one other component (e.g., a hardware or software component) of the electronic device 101 connected to the processor 150 and may process or compute various data.

Hereinbelow, a description will be made of a method in which the electronic device 101 according to an embodiment of the present disclosure determines abnormality of the one or more battery cells 111, 113, or 115 included in the battery module 110.

In an embodiment, the electronic device 101 may obtain state values (e.g., one or more values related to voltage, current, resistance, charge state, health state, or temperature) of the one or more battery cells 111, 113, or 115. In an embodiment, the electronic device 101 may obtain state values of the one or more battery cells 111, 113, or 115 for a designated time window (e.g., 180 seconds (sec)). In an embodiment, the electronic device 101 may obtain state values of the one or more battery cells 111, 113, or 115 in a designated time period (e.g., 0.1 second) for a designated time window. For example, the electronic device 101 may obtain voltage values of the one or more battery cells 111, 113, or 115. In another example, the electronic device 101 may obtain current values of the one or more battery cells 111, 113, or 115.

In an embodiment, the state values of the one or more battery cells 111, 113, or 115 obtained in a designated time period for a designated time window may be designated as ‘input data’. In an embodiment, the input data may be expressed as a matrix (e.g., an M×N matrix) including N values of M battery cells 111, 113, or 115. For example, the input data may include N voltage values of the M battery cells 111, 113, or 115. In another example, the input data may include one of N current, resistance, charge state, health state, or temperature values of the M battery cells 111, 113, or 115. For example, entries of the input data may indicate the voltage values of the M battery cells 111, 113, or 115. In another example, the entries of the input data may indicate one of resistance, charge state, health state, or temperature values of the M battery cells 111, 113, or 115. Herein, M indicates the number of battery cells 111, 113, or 115, and N indicates the number of time periods for obtaining state values of the battery cells 111, 113, or 115. For example, when the number of battery cells 111, 113, or 115 is 100, a designated time window is 180 seconds, and a designated time period is 0.1 second, M may be 100 and N may be 1800.

In an embodiment, input data Dᵢₙₚᵤₜ may be expressed as Equation 1.

$${D}_{input} = ( \begin{matrix}{v}_{1 , 1} & ⋯ & {v}_{1 , N} \\ ⋮ & ⋱ & ⋮ \\ {v}_{M , 1} & ⋯ & {V}_{M , N}\end{matrix} ) \qquad [ Equation l ]$$

In Equation 1, respective entries v_{1,1}, . . . , v_{1,N} to v_{M,1}, . . . , v_{M,N} of the input data Dᵢₙₚᵤₜ may indicate the state values of the battery cells 111, 113, or 115. Respective columns (or column vectors) of the input data Dᵢₙₚᵤₜ may indicate M state values obtained for the same time period (or a sensing time of the sensor circuit 120). Respective rows (or row vectors) of the input data Dᵢₙₚᵤₜ may indicate N state values respectively obtained from the battery cells 111, 113, or 115 for a designated time period. For example, the entries v_{1,1} to v_{M,1} of the first column vector may be state values of the battery cells 111, 113, or 115 obtained for the first time period. The entries v_{1,1} to v_{1,N} of the first row vector may be state values obtained from the first battery cell for a designated time period. In an embodiment, the respective entries v_{1,1}, . . . , v_{1,N} to v_{M,1}, . . . , v_{M,N} of the input data Dᵢₙₚᵤₜ may indicate the state values of the same type. For example, the entries v_{1,1}, . . . , v_{1,N} to v_{M,1}, . . . , v_{M,N} may indicate state values of one type of voltage, current, resistance, charge state, health state, or temperature.

In an embodiment, the electronic device 101 may obtain standardized data based on input data. In an embodiment, standardized data of random matrix data may be obtained based on standardization over entries of respective column vectors of the random matrix data. In an embodiment, standardization may transforming values into standardized scores (or Z scores). For example, standardization may be based on Equation 2 below.

$${z}_{i , j} = \frac{{v}_{i , j} - {m}_{j}}{{σ}_{j}} \qquad [ Equation 2 ]$$

In Equation 2, z_{i,j} indicates a standardized score of a j^{th} entry of an i^{th} row vector of the random matrix data. v_{i,j} indicates a value of the j^{th} entry of the i^{th} row vector of the random matrix data. mⱼ indicates an average of entries of a j^{th} column vector of the random matrix data. σⱼ indicates a standard deviation of the entries of the j^{th} column vector of the random matrix data. Herein, i indicates an integer of 1 or greater and less than or equal to the number of rows of the random matrix data, and j indicates an integer of 1 or greater and less than or equal to the number of columns of the random matrix data.

In an embodiment, the electronic device 101 may determine first state abnormality and/or second state abnormality of the battery cells 111, 113, or 115 based on the standardized data. In an embodiment, the electronic device 101 may determine the first state abnormality and/or the second state abnormality of the battery cells 111, 113, or 115 by using determination reference data based on the standardized data. In an embodiment, the determination reference data may be the standardized data. In an embodiment, the determination reference data may be data obtained by performing data processing (e.g., removing an offset, averaging a period, obtaining a change amount, and/or performing concatenation) on the standardized data. In an embodiment, the first state abnormality may mean state abnormality where an instantaneous voltage of a battery cell drops in charge of the battery cell. In an embodiment, the second state abnormality may mean state abnormality where a slope of a voltage of a battery cell decreases (or is low) in charge of the battery cell. In an embodiment, the first state abnormality may be determined based on a learning-based model, and the second state abnormality may be determined based on a scheme (e.g., a rule-based model) other than the learning-based model.

Hereinbelow, an operation of the electronic device 101 determining the first state abnormality of the battery cells 111, 113, or 115 will be described.

In an embodiment, the electronic device 101 may identify a row vector including an entry having a value less than or equal to a reference threshold standardized score among entries of respective row vectors of the determination reference data. According to an embodiment, the electronic device 101 may identify a row vector including an entry having a value greater than or equal to the reference threshold standardized score among the entries of the respective row vectors of the determination reference data. According to an embodiment, the electronic device 101 may identify a row vector including an entry having a value beyond a reference threshold standardized score range among the entries of the respective row vectors of the determination reference data. In an embodiment, the reference threshold standardized score may be a score experimentally determined to extract a candidate having a possibility of the first state abnormality. Hereinbelow, it is illustrated that the electronic device 101 may identify the row vector including the entry having the value less than or equal to the reference threshold standardized score among the entries of the respective row vectors of the determination reference data.

In an embodiment, the electronic device 101 may obtain output vectors of the learning-based model based on the row vectors of the determination reference data. In an embodiment, the electronic device 101 may obtain the output vector of the row vector including the entry having the value less than or equal to the reference threshold standardized score, based on the learning-based model. In an embodiment, the learning-based model may be an auto encoder. In an embodiment, the auto encoder may be an artificial neural network trained to reconstruct determination reference data corresponding to a normal behavior. In an embodiment, the auto encoder may be an artificial neural network trained in an unsupervised manner. In an embodiment, the auto encoder may include an encoder and a decoder. In an embodiment, the encoder of the auto encoder may compress an input into lower dimensions, and the decoder of the auto encoder may reconstruct a compressed output of the auto encoder into previous dimensions. Thus, the input and the output of the auto encoder may have the same dimensions, and the output of the auto encoder may have a form including a reconstruction error (or a reconstruction loss) in addition to the input of the auto encoder.

In an embodiment, the electronic device 101 may determine the first state abnormality of the battery cell based on the output vector of the learning-based model. In an embodiment, the electronic device 101 may determine the first state abnormality of the battery cell based on the reconstruction error of the auto encoder. In an embodiment, a reconstruction error or a random row vector may be a root mean square (RMS) of a vector obtained by subtracting an output vector for the random row vector from the random row vector.

In an embodiment, the electronic device 101 may identify a row vector in which the reconstruction error exceeds a designated reference reconstruction error, among row vectors of the determination reference data. In an embodiment, the electronic device 101 may determine that a battery cell related to a row vector exceeding a reference reconstruction error has the first state abnormality. In an embodiment, the reference reconstruction error may be an error experimentally determined to identify the first state abnormality.

Hereinbelow, an operation of the electronic device 101 determining the second state abnormality of the battery cells 111, 113, or 115 will be described.

In an embodiment, the electronic device 101 may determine the second state abnormality of the battery cells 111, 113, or 115 based on a sum of entries of respective row vectors of the determination reference data. In an embodiment, the electronic device 101 may identify a row vector corresponding to a sum being less than or equal to a designated reference sum value, among row vectors. According to an embodiment, the electronic device 101 may identify a row vector corresponding to a sum being greater than or equal to the designated reference sum value, among the row vectors. According to an embodiment, the electronic device 101 may identify a row vector corresponding to a sum falling beyond a designated reference sum range, among the row vectors. Hereinbelow, it will be illustrated that the electronic device 101 may identify the row vector corresponding to a sum being greater than or equal to the designated reference sum value, among the row vectors. In an embodiment, the reference sum value may be a value experimentally determined to identify the second state abnormality.

In an embodiment, the electronic device 101 may determine that a battery cell related to the row vector less than or equal to the designated reference sum value has the second state abnormality.

In an embodiment, the electronic device 101 may provide a notification to a user through an output device (or a display or the communication circuit 130) when a battery cell including state abnormality is identified. In an embodiment, the notification provided to the user may include a notification to check abnormality of a battery cell, a notification to replace a battery cell, or a combination thereof.

While it is shown in FIG. 1 that the electronic device 101 obtains standardized data of input data and determines first state abnormality and/or second state abnormality based on determination reference data of standardized data, but this is merely an example. According to an embodiment, the electronic device 101 may perform processing to process the input data and determine the first state abnormality and/or the second state abnormality based on standardized data of the processed input data. In addition, the electronic device 101 may perform processing to process the standardized data of the input data and determine the first state abnormality and/or the second state abnormality based on the processed standardized data (or the determination reference data). According to an embodiment, processing of the input data and/or processing of the standardized data may be selectively performed.

Hereinbelow, examples will be described where the electronic device 101 according to an embodiment of the present disclosure processes input data.

In an embodiment, the electronic device 101 may obtain smoothing data (or moving average data) of the input data. In an embodiment, smoothing of random matrix data may be performed among entries of respective row vectors of the random matrix data. For example, smoothing of the random matrix data may be performed based on Equation 3.

$${vs}_{i , j} = \frac{{\sum }_{k = j - d}^{j + d} {α}_{k} \times {v}_{i , k}}{2 d + 1} \qquad [ Equation 3 ]$$

In Equation 3, vs_{i,j} indicates a smoothed value of the j^{th} entry of the i^{th} row vector of the random matrix data. d indicates a distance to the farthest entry from the j^{th} entry among entries used for smoothing. k indicates an integer greater than or equal to (j−d) and less than or equal to (j+d). αk indicates a weight value applied to a k^{th} entry. v_{i,k} indicates a value of the k^{th} entry of the i^{th} row. A sum of weight values used for smoothing the j^{th} entry of the i^{th} row vector of the rando matrix data may be 1. When the weight values used for smoothing the j^{th} entry of the i^{th} row vector of the rando matrix data are equal to each other, smoothing may be moving averaging.

In an embodiment, the electronic device 101 may obtain smoothing data (or moving average data) of input data, obtain standardized data of the obtained smoothing data (or the moving average data), and determine the first state abnormality and/or the second state abnormality based on the standardized data.

In an embodiment, the electronic device 101 may obtain data by removing an offset from the input data. In an embodiment, the offset of the random matrix data may be set for each row vector of the random matrix data. In an embodiment, the offset for the random matrix data may be a value of the first entry among the entries of the respective row vectors of the random matrix data. In an embodiment, removal of the offset for the random matrix data may involve subtracting an offset from each row vector of each entry of row vectors of the random matrix data.

In an embodiment, the electronic device 101 may obtain data by removing an offset from input data, obtain standardized data of the obtained offset-removed data, and determine the first state abnormality and/or the second state abnormality based on the standardized data.

In an embodiment, the electronic device 101 may sequentially perform offset removal and smoothing with respect to the input data. In an embodiment, the electronic device 101 may obtain standardized data of data obtained by sequentially performing offset removal and smoothing, and determine the first state abnormality and/or the second state abnormality based on the standardized data. According to an embodiment, offset removal may be performed first on the input data and then smoothing may be performed, or smoothing may be performed with respect to the input data first and then offset removal may be performed.

Hereinbelow, examples will be described where the electronic device 101 according to an embodiment of the present disclosure processes the standardized data to obtain the determination reference data. The standardized data described below may be the standardized data of the input data, the standardized data of the smoothed input data, the standardized data of the offset-removed input data, or the standardized data of smoothed and offset-removed input data.

In an embodiment, the electronic device 101 may obtain the determination reference data by removing an offset from the standardized data. In an embodiment, the electronic device 101 may determine the first state abnormality and/or the second state abnormality based on the offset-removed standardized data (i.e., determination reference data).

In an embodiment, the electronic device 101 may obtain period average data of the standardized data as the determination reference data. In an embodiment, the period averaging may involve averaging the entries of the respective row vectors of the random matrix data every designated time intervals (e.g., 18 seconds). In an embodiment, the time intervals may not overlap each other. For example, when a designated time interval is 18 seconds, a designated time window is 180 seconds, and a designated time period is 0.1 second, then the number of columns of window average data is 10 and the columns of the window average data may indicate an average of 180 columns of the standardized data.

In an embodiment, the electronic device 101 may determine the first state abnormality and/or the second state abnormality based on the window average data (i.e., determination reference data).

In an embodiment, the electronic device 101 may obtain change amount data of the standardized data as the determination reference data. In an embodiment, the change amount may be a difference value between adjacent entries of each row vector of the random matrix data. For example, a change amount of a random entry may be a value obtained by subtracting a value of an entry previous to the random entry from a value of the random entry.

In an embodiment, the electronic device 101 may determine the first state abnormality and/or the second state abnormality based on the change amount data (i.e., determination reference data).

In an embodiment, the electronic device 101 may obtain concatenation data of the standardized data as the determination reference data. In an embodiment, concatenation of random matrix data may concatenate other matrix data than the random matrix data in a column direction. In an embodiment, concatenation of the random matrix data may involve sequentially concatenating the random matrix data except for the first column, the first column of the random matrix data, and the last column of the random matrix data. In an embodiment, the electronic device 101 may determine the first state abnormality and/or the second state abnormality based on the concatenation data (i.e., determination reference data).

In an embodiment, the electronic device 101 may obtain the determination reference data by sequentially removing an offset, averaging a window, obtaining a change amount, and performing concatenation for the standardized data. In an embodiment, the electronic device 101 may determine the first state abnormality and/or the second state abnormality based on the determination reference data obtained by sequentially removing an offset, averaging a window, obtaining a change amount, and performing concatenation for the standardized data. The order of removing an offset, averaging a window, obtaining a change amount, and performing concatenation for the standardized data may be set differently according to embodiments.

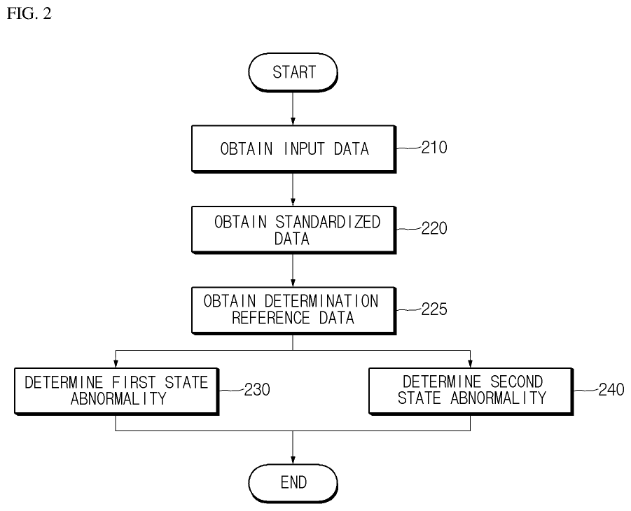

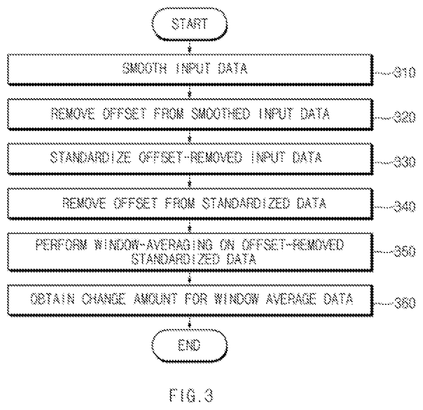

FIG. 2 is a flowchart illustrating operations of an electronic device according to an embodiment of the present disclosure. Operations shown in FIG. 2 may be executed by the electronic device 101 of FIG. 1.

Referring to FIG. 2, in operation 210, the electronic device 101 may obtain input data. In an embodiment, the input data may include respective state values of the one or more battery cells 111, 113, or 115 obtained in a designated time period for a designated time window. In an embodiment, the input data may be expressed as a matrix (e.g., an M×N matrix) including N values of M battery cells 111, 113, or 115. For example, entries of the input data may indicate the voltage values of the M battery cells 111, 113, or 115. In another example, the entries of the input data may indicate one of resistance, charge state, health state, or temperature values of the M battery cells 111, 113, or 115. Herein, M indicates the number of battery cells 111, 113, or 115, and N indicates the number of time periods for obtaining state values of the battery cells 111, 113, or 115.

In operation 220, the electronic device 101 may obtain the standardized data. In an embodiment, the standardized data may be standardized data among respective entries of column vectors of the input data.

In operation 225, the electronic device 101 may obtain determination reference data based on the standardized data. In an embodiment, the determination reference data may be the standardized data. In an embodiment, the determination reference data may be data obtained by performing data processing (e.g., removing an offset, averaging a period, obtaining a change amount, and/or performing concatenation) on the standardized data.

In operation 230, the electronic device 101 may determine the first state abnormality. In an embodiment, the electronic device 101 may obtain output vectors of the learning-based model based on the row vectors of the determination reference data. In an embodiment, the electronic device 101 may determine the first state abnormality of the battery cell based on the output vector of the learning-based model.

In an embodiment, the electronic device 101 may determine the first state abnormality of the battery cell based on the reconstruction error of the auto encoder. In an embodiment, a reconstruction error or a random row vector may be an RMS of a vector obtained by subtracting an output vector for the random row vector from the random row vector.

In an embodiment, the electronic device 101 may identify a row vector in which the reconstruction error exceeds a designated reference reconstruction error, among row vectors of the determination reference data. In an embodiment, the electronic device 101 may determine that a battery cell related to a row vector exceeding a reference reconstruction error has the first state abnormality.

In operation 240, the electronic device 101 may determine the second state abnormality. In an embodiment, the electronic device 101 may determine the second state abnormality of the battery cells 111, 113, or 115 based on a sum of respective entries of row vectors of the determination reference data. In an embodiment, the electronic device 101 may identify a row vector corresponding to a sum being less than or equal to a designated reference sum value, among row vectors. In an embodiment, the electronic device 101 may determine that a battery cell related to the row vector less than or equal to the designated reference sum value has the second state abnormality.

While it is shown in FIG. 2 that the electronic device 101 obtains standardized data of input data and determines first state abnormality and/or second state abnormality based on determination reference data of standardized data, but this is merely an example. According to an embodiment, the electronic device 101 may perform processing to process the input data and determine the first state abnormality and/or the second state abnormality based on standardized data of the processed input data. In addition, the electronic device 101 may determine the first state abnormality and/or the second state abnormality based on the determination reference data obtained by performing processing to process the standardized data of the input data. According to an embodiment, processing of the input data and/or processing of the standardized data may be selectively performed.

In an embodiment, a method of the electronic device 101 processing the input data may include removing an offset from the input data and smoothing the input data. In an embodiment, a method of the electronic device 101 processing the standardized data to obtain the determination reference data may include removing an offset from the standardized data, window-averaging the standardized data, and obtaining a change amount of the standardized data.

While it is shown in FIG. 2 that both operations 230 and 240 are performed, this is merely an example. According to an embodiment, operation 230 and 240 may be performed selectively. In some embodiment, any one of operations 230 and 240 may not be performed. For example, the electronic device 101 may perform operation 230 to determine only the first state abnormality and may not perform operation 240. In another example, the electronic device 101 may perform operation 240 to determine only the second state abnormality and may not perform operation 230.

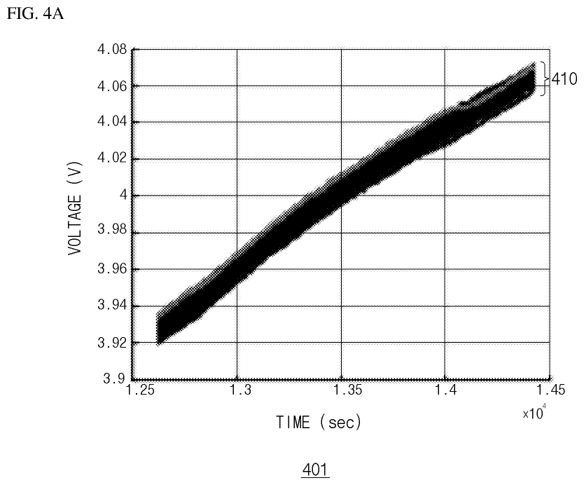

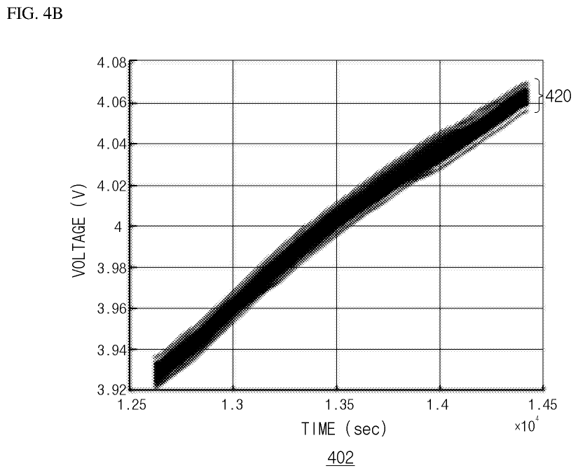

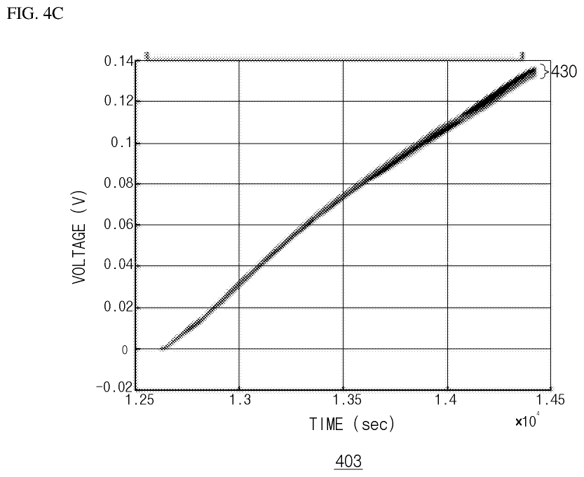

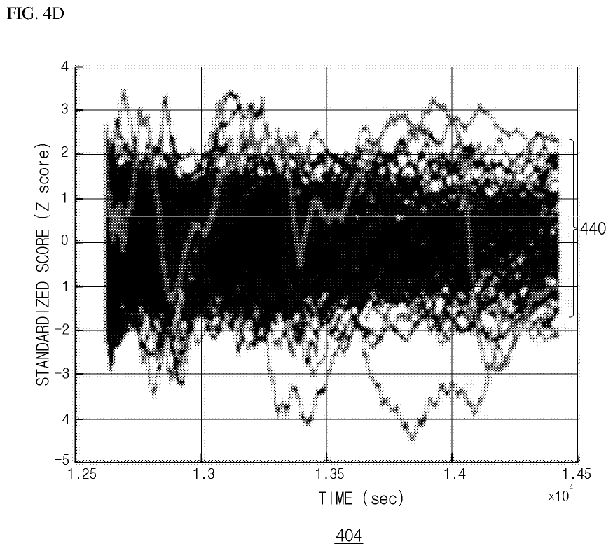

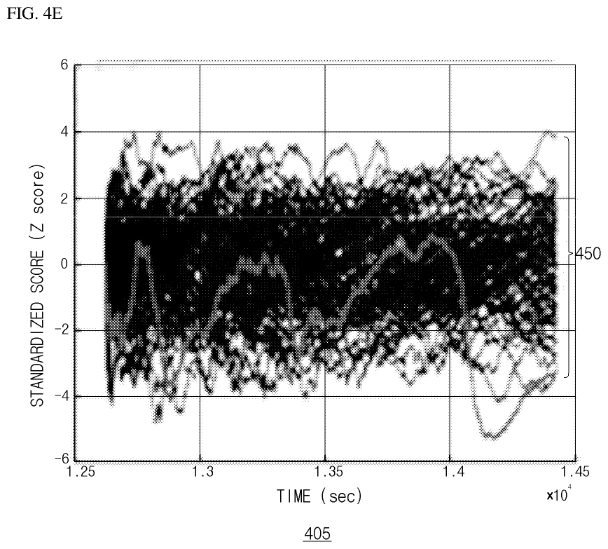

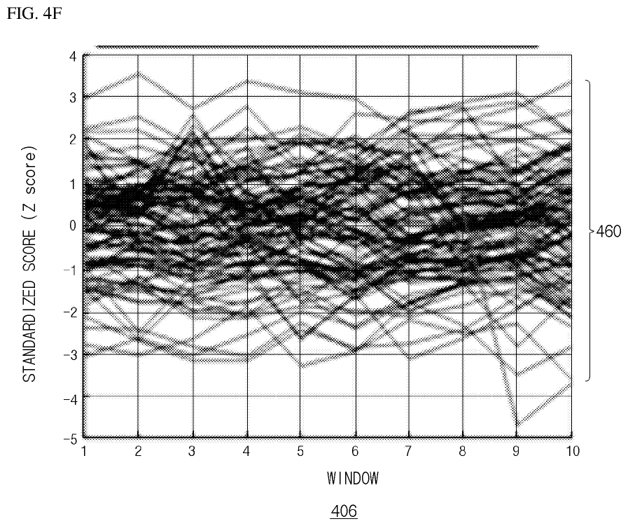

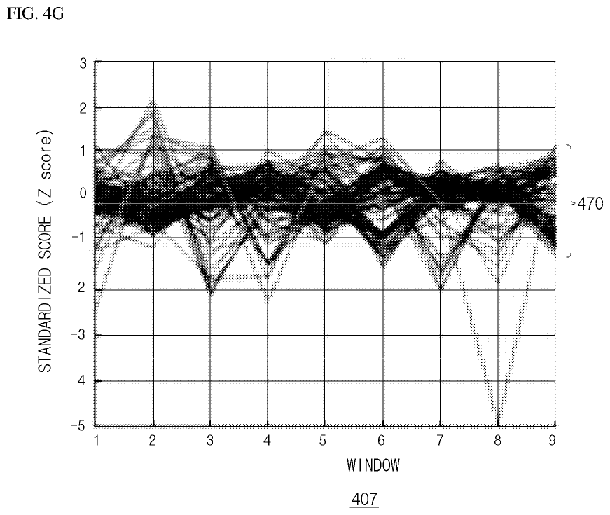

FIG. 3 is a flowchart illustrating operations of an electronic device according to an embodiment of the present disclosure. FIG. 4A illustrates input data. FIG. 4B illustrates smoothed input data. FIG. 4C illustrates offset-removed input data. FIG. 4D illustrates standardized data of offset-removed input data. FIG. 4E illustrates offset-removed standardized data. FIG. 4F illustrates window average data of standardized data. FIG. 4G illustrates change amount data of window average data. Operations 310, 320, and 330 of FIG. 3 may be included in operation 220 of FIG. 2. Operations 340, 350, and 360 of FIG. 3 may be included in operation 225 of FIG. 2. Operations shown in FIG. 3 may be executed by the electronic device 101 of FIG. 1. In an embodiment, change amount data of FIG. 4G may be understood as determination reference data obtained by operations of FIG. 3.

Referring to FIG. 3, in operation 310, the electronic device 101 may perform smoothing on input data.

In an embodiment, the input data may include respective state values of the one or more battery cells 111, 113, or 115 obtained in a designated time period for a designated time window. In an embodiment, the input data may be expressed as a matrix (e.g., an M×N matrix) including N values of M battery cells 111, 113, or 115. In an embodiment, the state values may be one or more values related to voltage, current, resistance, charge state, health state, or temperature.

Referring to FIG. 4A, a graph 401 may indicate input data 410. The input data 410 may be voltage values of M battery cells 111, 113, or 115 obtained for a time window of 180 seconds.

In an embodiment, smoothing of the input data 410 may be performed among entries of respective row vectors of the input data. For example, smoothing of the input data 410 may be performed based on Equation 3.

Referring to FIG. 4B, a graph 402 may indicate the smoothed input data 420. Compared to the graph 401, the graph 402 shows that noise of the input data 420 is reduced by smoothing.

In operation 320, the electronic device 101 may remove an offset of the smoothed input data 420. In an embodiment, the offset of the smoothed input data 420 may be set for each row vector of the smoothed input data 420. In an embodiment, the offset of the smoothed input data 420 may be the first entry value of the respective entries of the row vectors of the smoothed input data 420. In an embodiment, offset removal from the smoothed input data 420 may involve subtracting an offset of each row vector from respective entries of the row vectors of the smoothed input data 420.

Referring to FIG. 4C, a graph 403 may indicate offset-removed input data 430. Compared to the graph 402, the graph 403 shows that an initial value of the input data 430 starts with 0.

In operation 330, the electronic device 101 may perform standardization on the offset-removed input data 430. In an embodiment, the standardized data of the input data 430 may be obtained based on standardization among entries of respective column vectors of the input data 430. In an embodiment, standardization may transforming values into standardized scores (or Z scores). For example, standardization may be based on Equation 2 below.

Referring to FIG. 4D, a graph 404 may indicate standardized data 440 of the input data 430.

In operation 340, the electronic device 101 may remove an offset of the standardized data 440.

In an embodiment, the offset of the standardized data 440 may be set for each row vector of the standardized data 440. In an embodiment, the offset of the standardized data 440 may be the first entry value of the respective entries of the row vectors of the standardized data 440. In an embodiment, offset removal from the standardized data 440 may involve subtracting an offset of each row vector from respective entries of the row vectors of the standardized data 440.

Referring to FIG. 4E, a graph 405 may indicate offset-removed standardized data 450.

In operation 350, the electronic device 101 may perform window-averaging on the offset-removed standardized data 450. In an embodiment, the window averaging may involve averaging the entries of the respective row vectors of the standardized data 450 every designated time intervals (e.g., 18 seconds). For example, when a designated time interval is 18 seconds, a designated time window is 180 seconds, and a designated time period is 0.1 second, then the number of columns of window average data is 10 and the columns of the window average data may indicate an average of 180 columns of the standardized data.

Referring to FIG. 4F, a graph 406 may indicate window averaging data 460. Compared to the graph 405 of FIG. 4E, it may be seen that there are 10 windows in the graph 406.

In operation 360, the electronic device 101 may obtain a change amount for the window average data 460. In an embodiment, the change amount may be a difference value between adjacent entries of each row vector of the window average data 460. For example, a change amount of a random entry may be a value obtained by subtracting a value of an entry previous to the random entry from a value of the random entry.

Referring to FIG. 4G, a graph 407 may indicate change amount data 470. Compared to the graph 407 of FIG. 4G, it may be seen that there are 9 windows in the graph 407. This is because there is one entry (e.g., the last entry) for which the change amount is not obtained in the graph 407.

Thereafter, the electronic device 101 may determine first state abnormality and/or second state abnormality of the battery cells 111, 113, or 115 based on the change amount data 470.

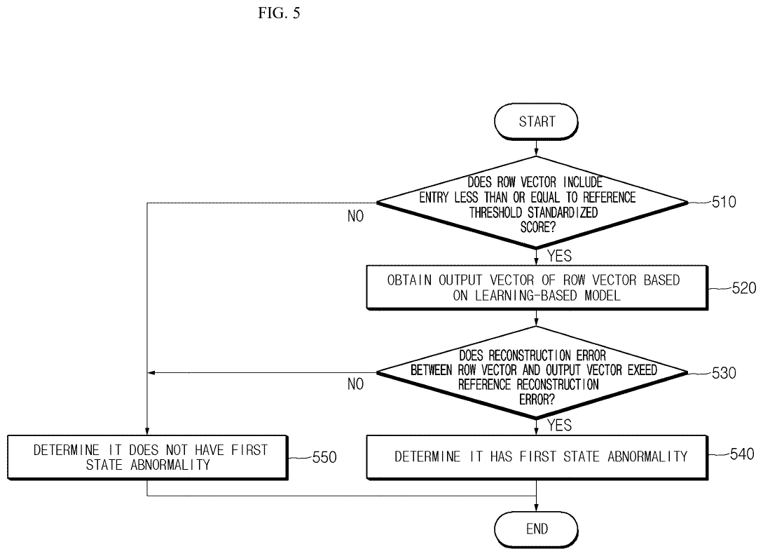

FIG. 5 is a flowchart illustrating operations of an electronic device according to an embodiment of the present disclosure. Operations of FIG. 5 may be included in operation 230 of FIG. 2. Operations shown in FIG. 5 may be executed by the electronic device 101 of FIG. 1.

Operations of FIG. 5 may be performed for each row vector.

Referring to FIG. 5, in operation 510, the electronic device 101 may determine whether a row vector includes an entry less than or equal to a reference threshold standardized score. In an embodiment, the electronic device 101 may identify a row vector including an entry having a value less than or equal to a reference threshold standardized score among entries of respective row vectors of the determination reference data. According to an embodiment, the row vector may be a row vector of the change amount data 470 of FIG. 4F. According to an embodiment, the row vector may be a row vector of data concatenating the change amount data 470. In an embodiment, the row vector may be a row vector of data that sequentially concatenates the change amount data 470 except for the first column, the first column of the change amount data 470, and the last column of the change amount data 470.

In operation 520, the electronic device 101 may obtain an output vector of a row vector based on the learning-based model. In an embodiment, the learning-based model may be an auto encoder. In an embodiment, the auto encoder may be an artificial neural network trained to reconstruct determination reference data corresponding to a normal behavior. In an embodiment, the output vector may have the same dimensions as the row vector and include a reconstruction error (or a reconstruction loss).

In operation 530, the electronic device 101 may determine whether the reconstruction error between the row vector and the output vector exceeds a reference reconstruction error. In an embodiment, the reconstruction error between the row vector and the output vector may be an RMS of a vector obtained by subtracting the row vector and the output vector.

In an embodiment, when the reconstruction error exceeds a reference reconstruction error, the electronic device 101 may perform operation 540. In an embodiment, when the reconstruction error does not exceed the reference reconstruction error, the electronic device 101 may perform operation 550.

In operation 540, the electronic device 101 may determine that it has the first state abnormality. In an embodiment, the electronic device 101 may determine that a battery cell corresponding to a row vector has the first state abnormality.

In operation 550, the electronic device 101 may determine that it does not have the first state abnormality. In an embodiment, the electronic device 101 may determine that the battery cell corresponding to the row vector does not have the first state abnormality.

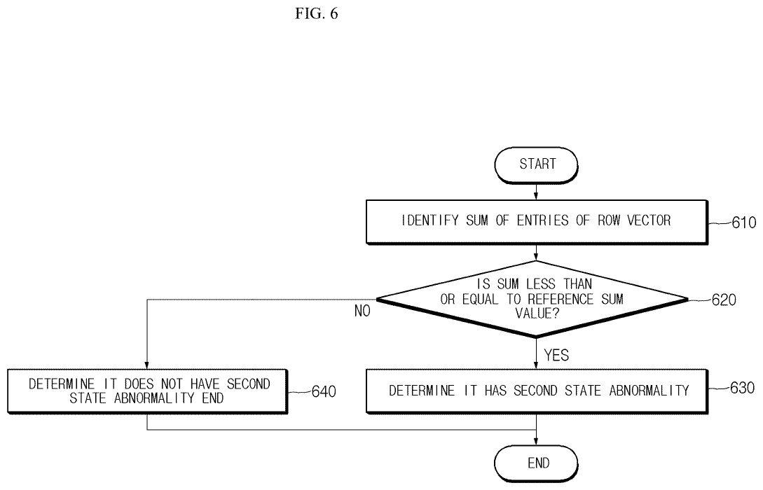

FIG. 6 is a flowchart illustrating operations of an electronic device according to an embodiment of the present disclosure. Operations of FIG. 6 may be included in operation 240 of FIG. 2. Operations shown in FIG. 6 may be executed by the electronic device 101 of FIG. 1.

Operations of FIG. 6 may be performed for each row vector.

Referring to FIG. 6, in operation 610, the electronic device 101 may identify a sum of entries of a row vector. According to an embodiment, the row vector may be a row vector of the change amount data 470 of FIG. 4F.

In operation 620, the electronic device 101 may determine whether the sum is less than or equal to a reference sum value.

In an embodiment, when the sum is less than or equal to the reference sum value, the electronic device 101 may perform operation 630. In an embodiment, when the sum is not less than or equal to the reference sum value, the electronic device 101 may perform operation 640.

In operation 630, the electronic device 101 may determine that is has the second state abnormality. In an embodiment, the electronic device 101 may determine that a battery cell corresponding to a row vector has the second state abnormality.

In operation 640, the electronic device 101 may determine that it does not have the second state abnormality. In an embodiment, the electronic device 101 may determine that the battery cell corresponding to the row vector does not have the second state abnormality.

1. An electronic device comprising:
a battery module comprising M battery cells, M being an integer greater than or equal to 2;
a detection circuit configured to obtain state values related to states of the M respective battery cells; and
a processor,
wherein the processor is configured to:
obtain input data through the detection circuit, wherein the input data is expressible as an M×N matrix, M×N entries of the input data indicate the state values of the M respective battery cells at different points in time, and N indicates a number of the points in time for obtaining the state values of the M respective battery cells;
standardize column vectors of the input data to obtain standardized data for the input data, wherein each of the column vectors comprises the entries of the input data obtained at an identical point in time;
obtain determination reference data based on the standardized data; and
determine first state abnormality and/or second state abnormality of each of the M battery cells based on values indicated by respective row vectors of the determination reference data,
wherein the first state abnormality is determined based on a learning-based model, and the second state abnormality is determined based on a scheme other than the learning-based model.

2. The electronic device of claim 1, wherein the processor is further configured to:
identify, from among the respective row vectors of the determination reference data, a row vector comprising at least one value less than or equal to a reference threshold standardized score;
obtain an output vector for the identified row vector based on the learning-based model; and
determine the first state abnormality of a battery cell corresponding to the identified row vector, based on the output vector.

3. The electronic device of claim 1, wherein the processor is further configured to:
remove an offset from the entries of respective row vectors of the input data; and
standardize each of the column vectors of the offset-removed input data to obtain the standardized data,
wherein the offset is set for each of the respective row vectors of the input data, and the offset is set as a value of a first entry from among the entries of the respective row vectors of the input data.

4. The electronic device of claim 1, wherein the processor is further configured to:
smooth the entries of the respective row vectors of the input data; and
standardize each of the column vectors of the smoothed input data to obtain the standardized data.

5. The electronic device of claim 1, wherein the processor is further configured to:
obtain a window average value of each row vector of the standardized data as the determination reference data; and
determine the first state abnormality and/or the second state abnormality of each of the M battery cells based on the window average values of the respective row vectors of the determination reference data,
wherein the window average values are average values of the entries of the respective row vectors of the standardized data included in different time windows, and the time windows do not overlap one another.

6. The electronic device of claim 1, wherein the processor is further configured to:
obtain change amounts of the entries of respective row vectors of the standardized data as the determination reference data; and
determine first state abnormality and/or second state abnormality of each of the M battery cells based on the change amounts of the entries of respective row vectors of the determination reference data.

7. The electronic device of claim 1, wherein the processor is further configured to:
identify a sum of the entries of each respective row vectors of the determination reference data;
identify, from among the row vectors of the determination reference data, a row vector for which its sum is less than or equal to a threshold sum value; and
determine that a battery cell corresponding to the identified row vector has the second state abnormality.

8. The electronic device of claim 1, wherein the learning-based model is an auto encoder, and the auto encoder is trained based on state values of normal battery cells.

9. An operating method of an electronic device, the operating method comprising:
obtaining input data through a detection circuit of the electronic device, wherein the input data is expressible as an M×N matrix, M×N entries of the input data indicate the state values of M respective battery cells of the electronic device at different points in time, and N indicates a number of points in time for obtaining the state values of the M respective battery cells;
standardizing column vectors of the input data to obtain standardized data for the input data, wherein each of the column vectors comprises the entries of the input data obtained at an identical point in time;
obtaining determination reference data based on the standardized data; and
determining first state abnormality and/or second state abnormality of each of the M battery cells based on values indicated by the entries of respective row vectors of the determination reference data,
wherein the first state abnormality is determined based on a learning-based model, and the second state abnormality is determined based on a scheme other than the learning-based model.

10. The operating method of claim 9, wherein the determining of the first state abnormality and/or the second state abnormality comprises:
identifying, from among the respective row vectors of the determination reference data, a row vector comprising at least one value less than or equal to a reference threshold standardized score;
obtaining an output vector for the identified row vector based on the learning-based model; and
determining the first state abnormality of a battery cell corresponding to the identified row vector, based on the output vector.

11. The operating method of claim 9, wherein the obtaining of the standardized data comprises:
removing an offset from the entries of respective row vectors of the input data; and
standardizing each of the column vectors of the offset-removed input data to obtain the standardized data,
wherein the offset is set for each of the respective row vectors of the input data, and the offset is set as a value of a first entry from among the entries of the respective row vectors of the input data.

12. The operating method of claim 9, wherein the obtaining of the standardized data comprises:
smoothing the entries of the respective row vectors of the input data; and
standardizing each of the column vectors of the smoothed input data to obtain the standardized data.

13. The operating method of claim 9, wherein the obtaining of the determination reference data comprises obtaining a window average value of the row vectors of the standardized data as the determination reference data, and
the determining of the first state abnormality and/or the second state abnormality comprises determining the first state abnormality and/or the second state abnormality of each of the M battery cells based on the window average values of the respective row vectors of the determination reference data,
wherein the window average values are average values of the entries of the respective row vectors of the standardized data included in different time windows, and the time windows do not overlap one another.

14. The operating method of claim 9, wherein the obtaining of the determination reference data comprises obtaining change amounts of the entries of respective row vectors of the standardized data as the determination reference data, and
the determining of the first state abnormality and/or the second state abnormality comprises determining the first state abnormality and/or the second state abnormality of each of the M battery cells based on the change amounts of the entries of respective row vectors of the determination reference data.

15. The operating method of claim 9, wherein the determining of the first state abnormality and/or the second state abnormality comprises:
identifying a sum of the entries of each respective row vectors of the determination reference data;
identifying, from among the row vectors of the determination reference data, a row vector for which its sum is less than or equal to a threshold sum value; and
determining that a battery cell corresponding to the identified row vector has the second state abnormality.
